(19) United States
(12) Patent Application Publication
(10) Pub. No.: US 2019/0078909 A1
(43) Pub. Date: Mar. 14, 2019

(54) LOCALIZATION AND ATTITUDE ESTIMATION METHOD USING MAGNETIC FIELD AND SYSTEM THEREOF AND COMPUTER READABLE RECORDING MEDIUM HAVING THE SAME

(71) Applicant: INDUSTRIAL TECHNOLOGY RESEARCH INSTITUTE, Hsinchu (TW)

(72) Inventors: Sheng-Wen LUO, Kaohsiung City (TW); Kuan-Chun SUN, Baoshan Township (TW); Jwu-Sheng HU, Zhubei City (TW)

(21) Appl. No.: 15/828,012

(22) Filed: Nov. 30, 2017

(30) Foreign Application Priority Data
Sep. 13, 2017 (TW) 106131453

(51) Int. Cl. G01C 23/00; G01C 21/20; G01R 33/02

(52) U.S. Cl. CPC G01C 23/00; G01R 33/0206; G01C 21/20

(57) ABSTRACT

A localization and attitude estimation method using a magnetic field is provided. At least one set of three magnetic landmarks is set in a three-dimensional space, and any two of the three magnetic landmarks have different magnetic directions. The tri-axes magnetic sensor is used for sensing the magnetic fields of the three magnetic landmarks, and three magnetic components on the three axes of the current position of the tri-axes magnetic sensor are generated by a magnetic source separating method. After three non-linear equations are obtained according to the three magnetic components on the three axes of the current position of the tri-axes magnetic sensor, three non-linear equations are solved to obtain the position information of the tri-axes magnetic sensor, and attitude vectors of the tri-axes magnetic sensor in the three-dimensional space are estimated according to tri-axes magnetic vectors of the tri-axes magnetic sensor relative to the three magnetic landmarks.

This application claims the benefit of Taiwan application Serial No. 106131453, filed Sep. 13, 2017, the subject matter of which is incorporated herein by reference.

### TECHNICAL FIELD

The disclosure relates in general to a localization method and a system thereof, and more particularly to a localization and attitude estimation method using a magnetic field and a system thereof, and a computer readable recording medium having the same.

### BACKGROUND

Automated guided vehicle (AGV) is an important carrier in automated material transfer field. In comparison to the conventional transfer method using a conveyor, the AGV occupies less space and can be more flexibly adjusted in the production line. Further, the localization of the current trackless AGV is normally achieved through a laser reflective label, a magnetic landmark, or a two-dimensional bar code label. However, in the practical application of the label localization exemplified above, the space site needs to be cleared beforehand, and such manner is hard to be used for those plants lack of pre-planning site. Besides, the above label localization is limited to two-dimensional plane only and cannot be used in three-dimensional measurement such that it cannot judge the attitude of the object in the three-dimensional space, and therefore needs to be improved.

### SUMMARY

The disclosure is directed to a localization and attitude estimation method using a magnetic field, a system thereof, and a computer readable recording medium having the above method in which the tri-axes magnetic sensor disposed on an object (such as a movable carrier) is used to localize the object in the three-dimensional space and estimate the attitude of the object.

According to one embodiment of the disclosure, a localization and attitude estimation method using a magnetic field is provided for localizing a movable carrier having a tri-axes magnetic sensor disposed thereon. The localization and attitude estimation method includes following steps. Firstly, at least one set of three magnetic landmarks is set in a three-dimensional space, and any two of the three magnetic landmarks have different magnetic fields and different magnetic directions, and the position vectors and attitude vectors of at least one set of three magnetic landmarks in the three-dimensional space are known. Then, the magnetic fields of the three magnetic landmarks is sensed by a tri-axes magnetic sensor, and three magnetic components on the three axes of the current position of the tri-axes magnetic sensor are generated by a magnetic source separating method. Then, after three non-linear equations are obtained according to the three magnetic components on the three axes of the current position of the tri-axes magnetic sensor, the three non-linear equations are solved by an extended Kalman filter to obtain the position of the tri-axes magnetic sensor in the three-dimensional space, and attitude vectors of the tri-axes magnetic sensor are estimated according to tri-axes magnetic vectors of the tri-axes magnetic sensor relative to at least one set of three magnetic landmarks in the three-dimensional space.

According to another embodiment of the disclosure, a localization system using a magnetic field is provided. The localization system includes at least one set of three magnetic landmarks, a tri-axes magnetic sensor and a logical operation processing unit. The at least one set of three magnetic landmarks is disposed in a three-dimensional space, and any two of the three magnetic landmarks have different magnetic fields and different magnetic directions. The tri-axes magnetic sensor is disposed on a movable carrier. The logical operation processing unit is connected to the tri-axes magnetic sensor, which senses the magnetic fields of the three magnetic landmarks and generates at least three magnetic information to the logical operation processing unit. The logical operation processing unit calculates tri-axes magnetic vectors of the tri-axes magnetic sensor relative to at least one set of three magnetic landmarks and estimates a position information of the tri-axes magnetic sensor in the three-dimensional space.

A computer readable recording medium used for storing a computer program is provided. The computer program is loaded to a computer for performing the above localization and attitude estimation method using a magnetic field.

The above and other aspects of the disclosure will become better understood with regard to the following detailed description of the embodiment(s). The following description is made with reference to the accompanying drawings.

### BRIEF DESCRIPTION OF THE DRAWINGS

FIG. 1 is a flowchart of a localization and attitude estimation method using a magnetic field according to an embodiment of the disclosure.

FIG. 2 is a schematic diagram of a localization and attitude estimation system using a magnetic field according to an embodiment of the disclosure.

FIG. 3 is a schematic diagram of an extended localization range using a localization system of the disclosure.

### DETAILED DESCRIPTION

Detailed descriptions of the disclosure are disclosed below with a number of embodiments. However, the disclosed embodiments are for explanatory and exemplary purposes only, not for limiting the scope of protection of the disclosure. Designations common to the accompanying drawings are used to indicate identical or similar elements.

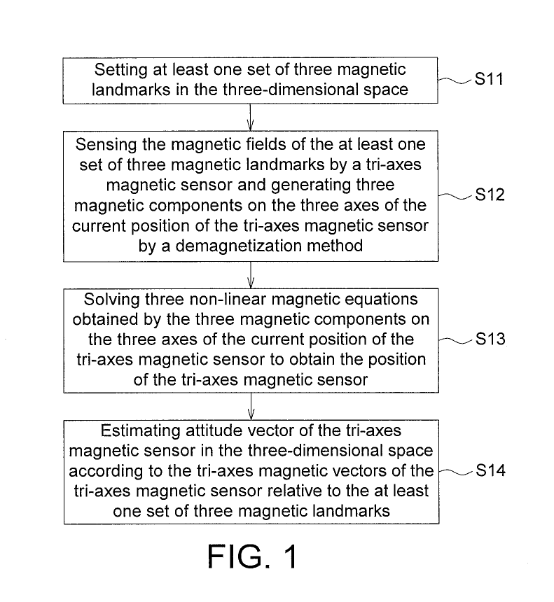

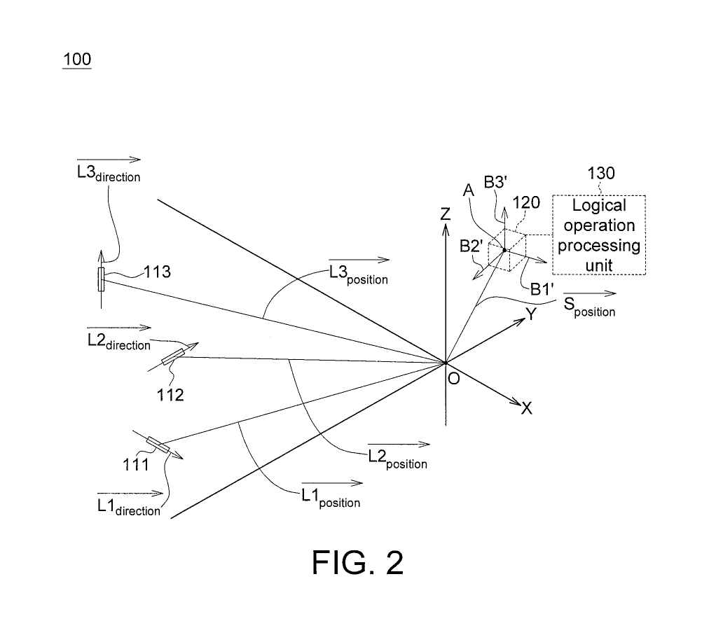

Refer to FIGS. 1 and 2. FIG. 1 is a flowchart of a localization and attitude estimation method using a magnetic field according to an embodiment of the disclosure. The localization and attitude estimation method using a magnetic field includes steps S11 to S14. Firstly, at step S11, at least one set of three magnetic landmarks 111-113 is set in a three-dimensional space (X, Y, Z). For example, the at least one set of three magnetic landmarks 111-113 is set on a ground, a wall, a ceiling or any position, and more magnetic landmarks can be set to extend the localization range.

Each of the magnetic landmarks 111-113 is used for generating a predetermined magnetic field. Each of the magnetic landmarks 111-113 can be a magnet or an electromagnet. Each of the magnetic landmarks 111-113 can have an N pole magnetic source and an S pole magnetic source or have multiple N pole magnetic sources and multiple S pole magnetic sources. The intensity of the magnetic field of each of the magnetic landmarks 111-113 is determined by the number of magnetic sources. Furthermore, each of the magnetic landmarks 111-113 can be realized by an active variable frequency magnetism generating element used for generating a magnetic signal having different fixed frequencies.

Referring to FIG. 2, a localization and attitude estimation system 100 using a magnetic field according to an embodiment of the disclosure includes at least one set of three magnetic landmarks 111-113, a tri-axes magnetic sensor 120 and a logical operation processing unit 130. The tri-axes magnetic sensor 120 is disposed on the movable carrier (not illustrated). When the movable carrier moves, at least one set of three magnetic landmarks 111-113 is disposed on the path or a surrounding area of the movable carrier, and the tri-axes magnetic sensor 120 disposed on the movable carrier is used for sensing the magnetic fields of the three magnetic landmarks 111-113.

In FIG. 2, three magnetic landmarks 111-113 are illustrated as an example, any two of the three magnetic landmarks 111-113 have different magnetic directions, and the position vectors (relative to the original point O) and attitude vectors of the at least one set of the three magnetic landmarks 111-113 in the three-dimensional space (X, Y, Z) are known. In the present embodiment, magnetic dipole electromagnetic landmarks are used as an example, and sine waves having different fixed frequencies are inputted to the three magnetic landmarks 111-113 to benefit the subsequent process of magnetic source separating method, and the position vectors of the three magnetic landmarks 111-113 in the three-dimensional space (X, Y, Z) are respectively expressed as: \vec{L1ₚₒₛᵢₜᵢₒₙ}, \vec{L2ₚₒₛᵢₜᵢₒₙ}, \vec{L3ₚₒₛᵢₜᵢₒₙ}, the attitude vectors are respectively expressed as: \vec{L1_{direction}}, \vec{L2_{direction}}, \vec{L3_{direction}}, wherein,

\vec{L1ₚₒₛᵢₜᵢₒₙ}=[a₁ b₁ c₁]^{T} ∈ R³, \vec{L1_{direction}}=[m₁ n₁ p₁]^{T} ∈ R³,

\vec{L2ₚₒₛᵢₜᵢₒₙ}=[a₂ b₂ c₂]^{T} ∈ R³, \vec{L2_{direction}}=[m₂ n₂ p₂]^{T} ∈ R³,

\vec{L3ₚₒₛᵢₜᵢₒₙ}=[a₃ b₃ c₃]^{T} ∈ R³, \vec{L3_{direction}}=[m₃ n₃ p₃]^{T} ∈ R³

The position information of the point under measurement A (that is, the tri-axes magnetic sensor 120) is unknown and can be expressed as: \vec{Sₚₒₛᵢₜᵢₒₙ}=(x,y,z).

In an embodiment, the three magnetic landmarks 111-113 in the three-dimensional space (X, Y, Z) are not settled on the same point and are not necessarily orthogonal to each other. That is, the three magnetic landmarks 111-113 are not limited to three orthogonal magnetic landmarks on the same point, and any three magnetic vectors will do as long as the sum of any two of the three magnetic vectors is not equivalent to any times of the remaining magnetic vector.

In step S12, the tri-axes magnetic sensor 120 is used for sensing the magnetic fields of the three magnetic landmarks 111-113 to obtain the sum of the magnetic vectors of the three magnetic landmarks 111-113 and perform a subsequent process of magnetic source separating method. In the present embodiment, the tri-axes magnetic sensor 120 is connected to the logical operation processing unit 130 to generate at least three magnetic information to the logical operation processing unit 130. For the convenience of calculating the magnetic components of the three magnetic landmarks 111-113, the magnetic fields of the three magnetic landmarks 111-113 can be divided by a magnetic source separating method, wherein the magnetic vectors of the three magnetic landmarks 111-113 are respectively expressed as: B₁, B₂, B₃, and the sum of the magnetic vectors is expressed as: B=₁+B₂+B₃, wherein

B₁=[B₁ₓ B_{1y} B_{1z}]^{T},

B₂=[B₂ₓ B_{2y} B_{2z}]^{T},

B₃=[B₃ₓ B_{3y} B_{3z}]^{T}

Then, the logical operation processing unit 130 uses a band-pass filter to obtain the three magnetic components of the magnetic vectors having three different fixed frequencies on the three axes of the current position of the tri-axes magnetic sensor 120, and the three magnetic components are respectively expressed as: B₁′, B₂′, B₃′ (as indicated in FIG. 2)

B′₁=[B′₁ₓ B′_{1y} B′_{1z}]^{T},

B′₂=[B′₂ₓ B′_{2y} B′_{2z}]^{T},

B′₃=[B′₃ₓ B′_{3y} B′_{3z}]^{T}

The logical operation processing unit 130 can be a computer, a single-ship microprocessor disposed in a computer, or a computer program stored in a computer readable recording medium. In another embodiment, the logical operation processing unit 130 is disposed on the movable carrier. Before receiving the magnetic information by the logical operation processing unit 130, a low-pass filter is used to reduce the noises of the magnetic information and increase the signal to noise ratio, and then an analog-to-digital converter is used to convert the magnetic information into digital magnetic information.

Then, at the step S13, after three non-linear magnetic equations are obtained according to the magnitudes of the three magnetic vectors, the three non-linear magnetic equations are solved by an extended Kalman filter or a linearization algorithm to obtain the position information (or the position vector) of the tri-axes magnetic sensor 120 in the three-dimensional space. In the present embodiment, the waveforms and amplitudes of the three magnetic landmarks 111-113 are analyzed by the extended Kalman filter with the limit conditions of three different fixed frequencies to obtain three sets of waveforms and amplitudes, that is, the three magnetic components of the three magnetic landmarks 111-113 on the three axes of the three-dimensional space (X, Y, Z). The non-linear magnetic equations are expressed as formula (1)

$$\vert \vert {B}_{1} {\vert \vert}^{2} = {μ}^{2} ( \frac{3 {( \vec{L {1}_{direction}} \cdot \vec{{r}_{1}} )}^{2}}{\vert \vert \vec{{r}_{1}} {\vert \vert}_{2}^{8}} + \frac{\vert \vert \vec{L {1}_{direction}} {\vert \vert}_{2}^{2}}{\vert \vert \vec{{r}_{1}} {\vert \vert}_{2}^{6}} ) = {h}_{1} ( \vec{{S}_{position}} ) \\ \vert \vert {B}_{2} {\vert \vert}^{2} = {μ}^{2} ( \frac{3 {( \vec{L {2}_{direction}} \cdot \vec{{r}_{2}} )}^{2}}{\vert \vert \vec{{r}_{2}} {\vert \vert}_{2}^{8}} + \frac{\vert \vert \vec{L {2}_{direction}} {\vert \vert}_{2}^{2}}{\vert \vert \vec{{r}_{2}} {\vert \vert}_{2}^{6}} ) = {h}_{2} ( \vec{{S}_{position}} ) \\ \vert \vert {B}_{3} {\vert \vert}^{2} = {μ}^{2} ( \frac{3 {( \vec{L {3}_{direction}} \cdot \vec{{r}_{3}} )}^{2}}{\vert \vert \vec{{r}_{3}} {\vert \vert}_{2}^{8}} + \frac{\vert \vert \vec{L {3}_{direction}} {\vert \vert}_{2}^{2}}{\vert \vert \vec{{r}_{3}} {\vert \vert}_{2}^{6}} ) = {h}_{3} ( \vec{{S}_{position}} ) \qquad ( 1 )$$

Wherein, \vec{r}ᵢ=[X Y Z]^{T} ∈ R³=\vec{Sₚₒₛᵢₜᵢₒₙ}−\vec{Liₚₒₛᵢₜᵢₒₙ},i=1,2,3, μis ¼π times of the constant value of the space magnetic field.

In the present embodiment, the non-linear magnetic equations can be linearized to obtain a linearized measurement matrix, a state equation and a measurement equation, wherein the linearized measurement matrix is expressed as formula (2)

$${H}_{all} = [ \begin{matrix}\frac{\partial {h}_{1}}{\partial X} {\vert}_{\vec{r} = \vec{{r}_{S}}} & \frac{\partial {h}_{1}}{\partial Y} {\vert}_{\vec{r} = \vec{{r}_{S}}} & \frac{\partial {h}_{1}}{\partial Z} {\vert}_{\vec{r} = \vec{{r}_{S}}} \\ \frac{\partial {h}_{2}}{\partial X} {\vert}_{\vec{r} = \vec{{r}_{S}}} & \frac{\partial {h}_{2}}{\partial Y} {\vert}_{\vec{r} = \vec{{r}_{S}}} & \frac{\partial {h}_{2}}{\partial Z} {\vert}_{\vec{r} = \vec{{r}_{S}}} \\ \frac{\partial {h}_{3}}{\partial X} {\vert}_{\vec{r} = \vec{{r}_{S}}} & \frac{\partial {h}_{3}}{\partial Y} {\vert}_{\vec{r} = \vec{{r}_{S}}} & \frac{\partial {h}_{3}}{\partial Z} {\vert}_{\vec{r} = \vec{{r}_{S}}}\end{matrix} ] \qquad ( 2 )$$

The state equation is expressed as formula (3)

$$S ( k + 1 ) = AS ( k ) + v ( k ) \\ A = [ \begin{matrix}1 & 0 & 0 \\ 0 & 1 & 0 \\ 0 & 0 & 1\end{matrix} ] \qquad ( 3 )$$

The measurement equation is expressed as formula (4)

y(k)=h(S(k))+w(k),h(S)=[h₁(\vec{Sₚₒₛᵢₜᵢₒₙ})h₂(\vec{Sₚₒₛᵢₜᵢₒₙ})h₃(\vec{Sₚₒₛᵢₜᵢₒₙ})]^{T} (4)

Wherein w(k) and v(k) respectively denote noises of the Gaussian distribution; w(k) and v(k) respectively have covariant matrixes Q_{M}, Q_{T}. The flow of the algorithm is as follows:

Measure update:
$\begin{matrix}K = \frac{{P}_{predict} {H}_{all}^{T}}{{H}_{all} {P}_{predict} {H}_{all}^{T} + {Q}_{M}} \\ P = ( I - {KH}_{all} ) {P}_{predict} \\ S = {S}_{predict} + K ( y - h ( {S}_{predict} ) )\end{matrix}$
Time update:
S_{predict} = AS
P_{predict} = APA^{T} +Q_{T}

Wherein, K denotes an optimal Kalman gain, P denotes a covariance estimation; A denotes a state conversion model; H denotes an observation model; h denotes a measurement equation; S denotes a state estimation.

Then, in the step S14, after the position information of the tri-axes magnetic sensor 120 in the three-dimensional space is obtained, the magnetic vectors B₁, B₂, and B₃ of the three magnetic landmarks 111-113 are known, the attitude transformation matrix of the tri-axes magnetic sensor 120 can be obtained through the comparison between the magnetic vectors B₁, B₂, B₃ and the magnetic components B₁′, B₂′, B₃′, and the attitude (such as azimuth angle, pitch angle and depression angle) of movable carrier can be obtained according to the attitude transformation matrix of the tri-axes magnetic sensor 120. The attitude transformation matrix R is expressed as:

R=[B′₁ B′₂ B′₃][B₁ B₂ B₃]⁻¹ and

det([B₁ B₂ B₃]) ≠ 0, that is, the determinant value of [B₁ B₂ B₃] is not equivalent to 0.

That is, in the step S14, based on the above algorithm, the logical operation processing unit 130 can calculate the three magnetic components B₁′, B₂′, B₃′ on the three axes of the current position of the tri-axes magnetic sensor 120 according to the position information of the tri-axes magnetic sensor 120 in the three-dimensional space (X, Y, Z) and can estimate the attitude vectors of the tri-axes magnetic sensor 120 in the three-dimensional space (X, Y, Z) according to the tri-axes magnetic vectors of tri-axes magnetic sensor 120 relative to the three magnetic landmarks 111-113.

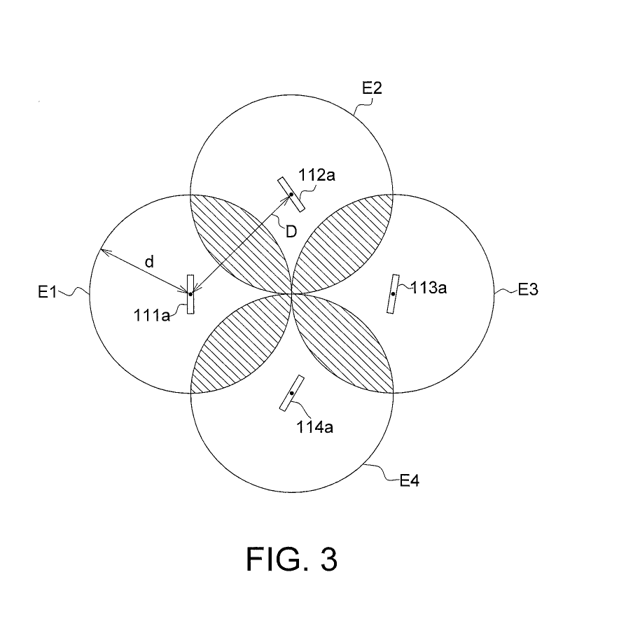

Refer to FIG. 3. The magnetic field generated by magnetic landmark decreases with the increase of the sensing distance. When the sensing distance is over a predetermined range, the tri-axes magnetic sensor 120 (refer to FIG. 2) will be unable to sense any change in the magnetic field. According to the magnetic source separating method of the disclosure, multiple magnetic landmarks 111a, 112a, 113a, and 114a are set on the path or surrounding area of the movable carrier, and three magnetic landmarks 111a, 112a, 114a with largest energy are selected from the multiple magnetic landmarks, so that the localization ranges E1-E4 can be extended. Let a circle with radius d be defined as a set point. According to the localization method, the distance D between two set points is set as a maximum value, and the space of the localization is completely covered by the landmarks. If the magnetic fields are differentiated using fixed frequencies, at least 4 sets of three magnetic landmarks (12 magnetic landmarks) having different fixed frequencies are set. The above method extends the localization ranges E1-E4, and at the same time provides a differentiation localization to each of the landmarks.

The localization and attitude estimation method using a magnetic field and the system thereof disclosed in above embodiments of the disclosure can be used to detect the position and attitude of a movable carrier (such as an unmanned vehicle or any object) in the space, and the arrangement of the magnetic landmarks 111-113 is not subjected to specific restrictions.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A localization and attitude estimation method using a magnetic field for localizing a movable carrier having a tri-axes magnetic sensor disposed thereon, the localization and attitude estimation method comprising:
setting at least one set of three magnetic landmarks in a three-dimensional space, wherein any two of the three magnetic landmarks have different magnetic directions;
wherein position vectors and attitude vectors of the at least one set of three magnetic landmarks in the three-dimensional space are known;
sensing magnetic fields of the at least one set of three magnetic landmarks by the tri-axes magnetic sensor and generating three magnetic components on three axes of current position of the tri-axes magnetic sensor by a magnetic source separating method; and
after three non-linear magnetic equations are obtained according to the three magnetic components on the three axes of the current position of the tri-axes magnetic sensor, solving the three non-linear magnetic equations by an extended Kalman filter to obtain a position information of the tri-axes magnetic sensor and estimating an attitude vector of the tri-axes magnetic sensor in the three-dimensional space according to tri-axes magnetic vectors of the tri-axes magnetic sensor relative to the at least one set of three magnetic landmarks.

2. The localization and attitude estimation method according to claim 1, wherein the magnetic source separating method comprises:
dividing the magentic fields of the at least one set of three magnetic landmarks into three magnetic components on three axes of the three-dimensional space by a band-pass filter; and
analyzing the waveforms and amplitudes of the three magnetic landmarks by an extended Kalman filter with a limit condition of three different fixed frequencies for the three magnetic landmarks to obtain three sets of waveforms and amplitudes used as the three magnetic components of the three magnetic landmarks on the three axes of the three-dimensional space.

3. The localization and attitude estimation method according to claim 1, wherein the at least one set of three magnetic landmarks in the three-dimensional space are not settled on a same point.

4. A localization system using a magnetic field for localizing a movable carrier, the localization system comprising:
at least one set of three magnetic landmarks disposed in a three-dimensional space, wherein any two of the three magnetic landmarks have different magnetic directions;
a tri-axes magnetic sensor disposed on the movable carrier; and
a logical operation processing unit connected to the tri-axes magnetic sensor, wherein the tri-axes magnetic sensor senses magnetic fields of the at least one set of three magnetic landmarks and generates at least three magnetic information to the logical operation processing unit, wherein the logical operation processing unit obtains tri-axes magnetic vectors of the tri-axes magnetic sensor relative to the at least one set of three magnetic landmarks by a magnetic source separating method and estimates a position information of the tri-axes magnetic sensor in the three-dimensional space.

5. The localization system according to claim 4, wherein the logical operation processing unit further calculates three magnetic components on three axes of a current position of the tri-axes magnetic sensor according to the position information of the tri-axes magnetic sensor in the three-dimensional space and estimates an attitude vector of the tri-axes magnetic sensor in the three-dimensional space according to the tri-axes magnetic vectors of the tri-axes magnetic sensor relative to the at least one set of three magnetic landmarks.

6. The localization system according to claim 4, wherein the logical operation processing unit comprises a single-ship microprocessor.

7. The localization system according to claim 5, wherein the logical operation processing unit divides the at least one set of three magnetic landmarks into the three magnetic components on the three axes of the current position of the tri-axes magnetic sensor by a band-pass filter, and analyzes the waveforms and amplitudes of the three magnetic landmarks by an extended Kalman filter with a limit condition of three different fixed frequencies for the three magnetic landmarks to obtain three sets of waveforms and amplitudes used as the three magnetic components of the three magnetic landmarks on three axes of the three-dimensional space.

8. The localization system according to claim 4, wherein each of the three magnetic landmarks comprises an active variable frequency magnetic generating element.

9. The localization system according to claim 4, wherein the at least one set of three magnetic landmarks in the three-dimensional space are not settled on a same point.

10. A non-transitory computer readable recording medium used for recording a computer program, wherein the computer program is loaded into a computer for performing the localization and attitude estimation method using a magnetic field as disclsoed in claim 1.
